(19) United States
(12) Patent Application Publication
(10) Pub. No.: US 2026/0114165 A1
(43) Pub. Date: Apr. 23, 2026

(54) DISPLAY APPARATUS HAVING A LIGHT-EMITTING DEVICE AND AN OPTICAL LENS

(71) Applicant: LG Display Co., Ltd., Seoul (KR)

(72) Inventors: You Yong JIN, Paju-si (KR); Joo Bong HYUN, Paju-si (KR); Sung Woo KIM, Paju-si (KR)

(73) Assignee: LG Display Co., Ltd., Seoul (KR)

(21) Appl. No.: 19/320,814

(22) Filed: Sep. 5, 2025

(30) Foreign Application Priority Data
Oct. 23, 2024 (KR) 10-2024-0145869

(51) Int. Cl. H10K 59/80; H10K 59/122

(52) U.S. Cl. CPC H10K 59/879; H10K 59/122

(57) ABSTRACT

A display apparatus can include a sub-pixel having a first light emitting region and a second light emitting region, a first optical element to receive light from the first light emitting region and configured to direct the light from the first light emitting region into a first viewing zone, a second optical element to receive light from the second light emitting region and configured to direct the light from the second light emitting region into a second viewing zone, and a light barrier structure disposed between the first and second light emitting regions and the first and second optical elements, the light barrier structure including at least a first opening corresponding to the light emitting region and at least a second opening corresponding to the second light emitting region. Also, a viewing angle of the first viewing zone is different than a viewing angle of the second viewing zone.

### CROSS-REFERENCE TO RELATED APPLICATIONS

This application claims priority to Korean Patent Application No. 10-2024-0145869, filed in the Republic of Korea on Oct. 23, 2024, the entirety of which is hereby incorporated by reference into the present application as if fully set forth herein.

### BACKGROUND

### Field of the Invention

The present disclosure relates to a display apparatus in which an optical lens is disposed on a light-emitting device.

### Discussion of the Related Art

Generally, a display apparatus provides an image to a user. For example, the display apparatus can include a plurality of light-emitting devices. Each of the light-emitting devices can emit light displaying a specific color. For example, each of the light-emitting devices can include a light-emitting unit between a lower electrode and an upper electrode.

In many environments, a single display screen is often viewed simultaneously by multiple individuals who may have different roles or information needs (e.g., a driver and a passenger in a car, etc.). Standard display technology is often designed to present a single, uniform image to all viewers. This limitation creates significant challenges, such as for safety and privacy.

For example, information that is desirable for one user can be an irrelevant and distracting source of clutter for another user who is trying to focus on a separate task. Similarly, in public or shared spaces, displaying sensitive or personal content becomes problematic, as there is no effective way to limit its visibility to the intended recipient.

Prior solutions to this issue are inadequate. They typically rely on either external optical films that degrade image quality for all viewers, or multiple separate displays that increase cost and complexity while creating a disjointed and aesthetically unpleasing interface. These approaches fail to offer a seamless, single panel solution for delivering differentiated content to multiple observers.

Thus, a need exists for an improved display technology that can provide a customized and seamless visual experience for multiple users from a single screen, enhancing safety by reducing distraction and securing privacy without degrading optical performance or requiring costly and cumbersome hardware.

Also, a need exists for a single display panel capable of simultaneously showing different images to different viewing positions in a manner that is both seamlessly integrated and optically efficient.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of simultaneously realize the images with different viewing angles.

Another object of the present disclosure is to provide a display apparatus capable of preventing or reducing the decrease in the lifespan and the unevenness in the reflection of the external light.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. A bank insulating layer is disposed on the device substrate. The bank insulating layer defines a first emission area and a second emission area in a sub-pixel. An optical insulating layer is disposed on the bank insulating layer. The optical insulating layer overlaps the first emission area and the second emission area. A first optical lens and a second optical lens are disposed on the optical insulating layer. The first optical lens overlaps the first emission area. The second optical lens overlaps the second emission area. A lower barrier pattern is disposed between the bank insulating layer and the optical insulating layer. The lower barrier pattern includes a first lower opening corresponding to the first emission area and a second lower opening corresponding to the second emission area. The first emission area and the second emission area have a planar shape of a bar extending in a first direction. A plane of the second optical lens has a different shape from a plane of the first optical lens.

The second optical lens can be disposed on a same layer as the first optical lens.

A length of the second emission area in the first direction can be different from a length of the first emission area in the first direction.

Light emitted from the second emission area can display a same color as light emitted from the first emission area.

A length of the first optical lens in the first direction can be greater than a length of the first emission area in the first direction. A length of the second optical lens in the first direction can be smaller than a length of the second emission area.

The first optical lens can have a planar shape extending parallel to the first emission area. A cross-section of the second optical lens in the first direction can have a semicircular shape.

A single first optical lens can be disposed within the first emission area. A plurality of second optical lenses can be disposed within the second emission area.

The plurality of second optical lenses can have a same planar shape.

An upper barrier pattern can be disposed on the optical insulating layer. The upper barrier pattern can overlap the lower barrier pattern. The upper barrier pattern can include a region overlapping with the second emission area.

The upper barrier pattern can include a different material from the lower barrier pattern.

In another embodiment, there is provided a display apparatus comprising a device substrate. The device substrate includes a first sub-pixel and a second sub-pixel. An optical insulating layer is disposed on the device substrate. The optical insulating layer overlaps the first sub-pixel and the second sub-pixel. A plurality of first optical lenses and a plurality of second optical lenses are disposed on the optical insulating layer. The plurality of first optical lenses overlaps a plurality of first emission areas defined in the first sub-pixel. The plurality of second optical lenses overlaps a second emission area defined in the second sub-pixel. A lower barrier pattern is disposed between the device substrate and the optical insulating layer. The lower barrier pattern includes a plurality of first lower opening overlapping with the plurality of first optical lenses and a second lower opening overlapping with the plurality of second optical lenses. Each of the first emission areas and each of the first lower openings have a planar shape corresponding to each of the first optical lenses. The second emission area and the second lower opening have a planar shape of a bar extending in a first direction. A plane of each second optical lens has a same shape as a plane of each first optical lens.

The plurality of second optical lenses can include a same material as the plurality of first optical lenses.

The plurality of first optical lenses and the plurality of second optical lenses can be disposed side by side in the first direction.

The second sub-pixel can display a same color as the first sub-pixel. The plurality of second optical lenses can have the same number as the plurality of first optical lenses.

A third optical lens and a fourth optical lens can be disposed on the optical insulating layer. A third emission area overlapping with the third optical lens can be defined in the first sub-pixel. A fourth emission area overlapping with the fourth optical lens can be defined in the second sub-pixel. The lower barrier pattern can include a third lower opening corresponding to the third emission area and a fourth lower opening corresponding to the fourth emission area. A plane of the third emission area and a plane of the fourth emission area can extend parallel to a plane of the second emission area. The third optical lens and the fourth optical lens can have a different planar shape from each first optical lens and each second optical lens.

The third optical lens and the fourth optical lens can be disposed on a same layer as the plurality of first optical lenses and the plurality of the second optical lenses.

A length of the fourth emission area in the first direction can be a same as a length of the third emission area in the first direction. A plane of the fourth optical lens can be a same shape as a plane of the third optical lens.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure, which are briefly described below.

FIG. 1 is a view schematically showing a location where a display apparatus according to an embodiment of the present disclosure is installed.

FIG. 2 is an enlarged view of K1 region in FIG. 1 according to an embodiment of the present disclosure.

FIG. 3 is an enlarged view of K2 region in FIG. 2 according to an embodiment of the present disclosure.

FIG. 4 is a view showing a circuit of a first sub-pixel in the display apparatus according to the embodiment of the present disclosure according to an embodiment of the present disclosure.

FIG. 5 is a view taken along I-I′ and II-II′ of FIG. 2 according to an embodiment of the present disclosure.

FIG. 6 is a view taken along III-III′ and IV-IV′ of FIG. 2 according to an embodiment of the present disclosure.

FIG. 7 is a view showing luminance according to a viewing angle of first light emitted from a second P-mode emission area and passing through second P-mode optical lenses on each second sub-pixel and second light emitted from a second S-mode emission area and passing through second S-mode optical lens on each second sub-pixel in the display apparatus according to the embodiment of the present disclosure.

FIGS. 8 to 12 are views showing the display apparatus according to embodiments of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

The features of various embodiments of the present disclosure can be partially or entirely coupled to or combined with each other and can be interlocked and operated in technically various ways, and the embodiments can be carried out independently of or in association with each other. Also, the term “can” used herein includes all meanings and definitions of the term “may.”

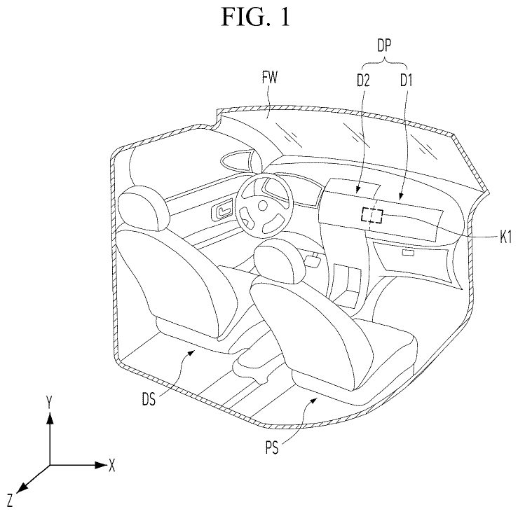

FIG. 1 is a view schematically showing a location where a display apparatus according to an embodiment of the present disclosure is installed.

Referring to FIG. 1, the display apparatus according to the embodiment of the present disclosure can include a display panel DP installed in a car. For example, an image realized by the display apparatus according to the embodiment of the present disclosure can be provided to a driver sitting in a driver seat DS and a passenger sitting in a passenger seat PS. In the display apparatus according to the embodiment of the present disclosure, the display panel DP can selectively provide the passenger with a different image from the driver. For example, in the display apparatus according to the embodiment of the present disclosure, a first image containing information unrelated to the operation of the car can be optionally provided to the passenger (e.g., entertainment content, movies, video, etc.), and a second image containing information necessary for the operation of the car can be provided to the driver (e.g., tachometer, navigation information, speed, time, warnings or notifications, etc.). The first image cannot be recognized by the driver or is not easily viewable by the driver. Thus, in the display apparatus according to the embodiment of the present disclosure, accidents due to gaze dispersion or distraction of the driver while driving the car can be prevented or reduced.

The first image can be realized simultaneously with the second image. For example, in the display apparatus according to the embodiment of the present disclosure, the display panel DP can include a first display area D1 for the realization of the first image and a second display area D2 for the realization of the second image. The second display area D2 can be disposed side by side with the first display area D1 in a first direction X. For example, the first display area D1 can be disposed in front of the passenger seat PS, and the second display area D2 can be disposed between the driver seat DS and the passenger seat PS.

A length of the second display area D2 in the first direction X can be different from a length of the first display area D1 in the first direction X. The second display area D2 can be in direct contact with the first display area D1. For example, a boundary between the first display area D1 and the second display area D2 can extend in a second direction Y perpendicular to the first direction X. Herein, a third direction Z perpendicular to the first direction X and the second direction Y can be a direction toward the driver seat DS and the passenger seat PS. A length of the second display area D2 in the second direction Y can be a same as a length of the first display area D1 in the second direction Y.

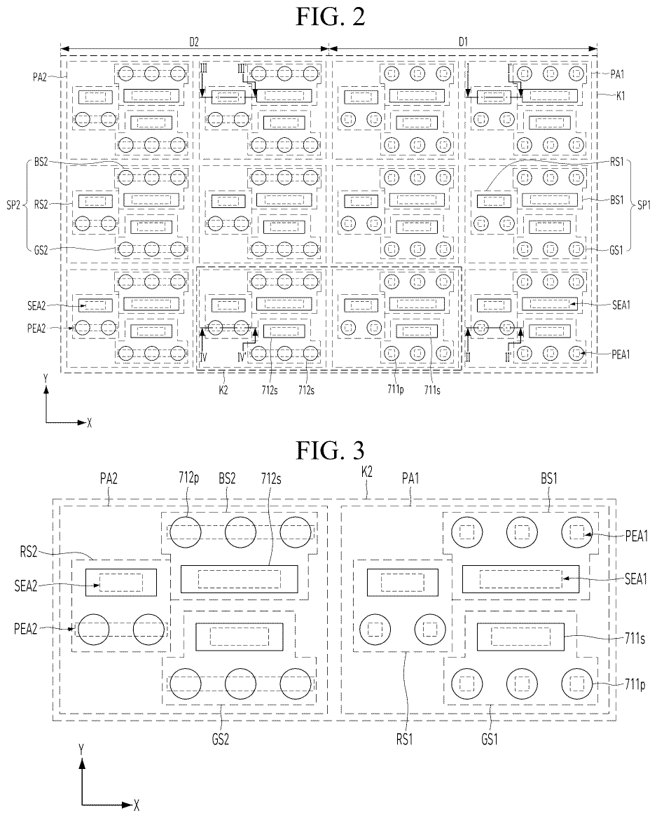

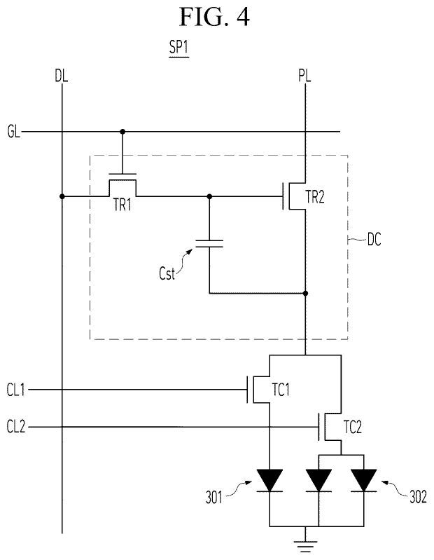

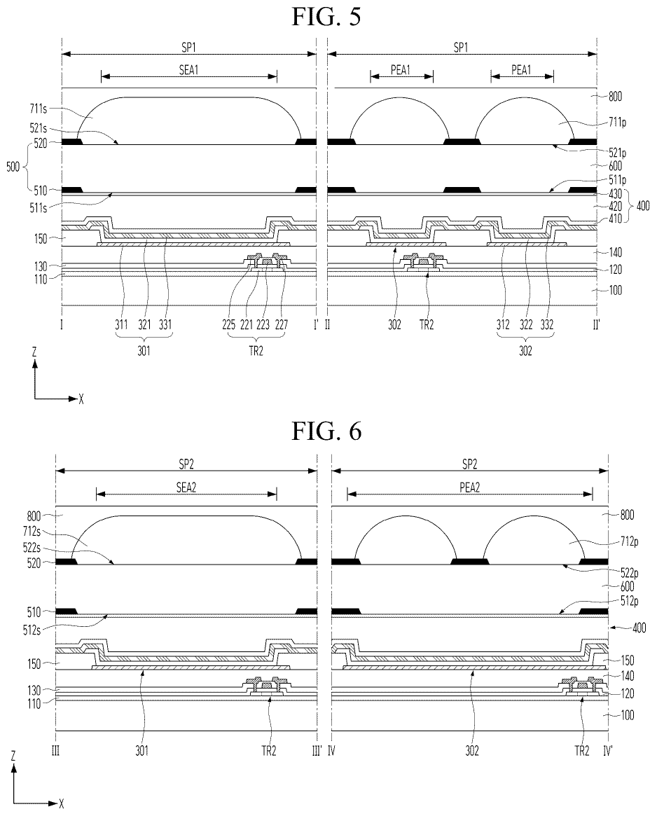

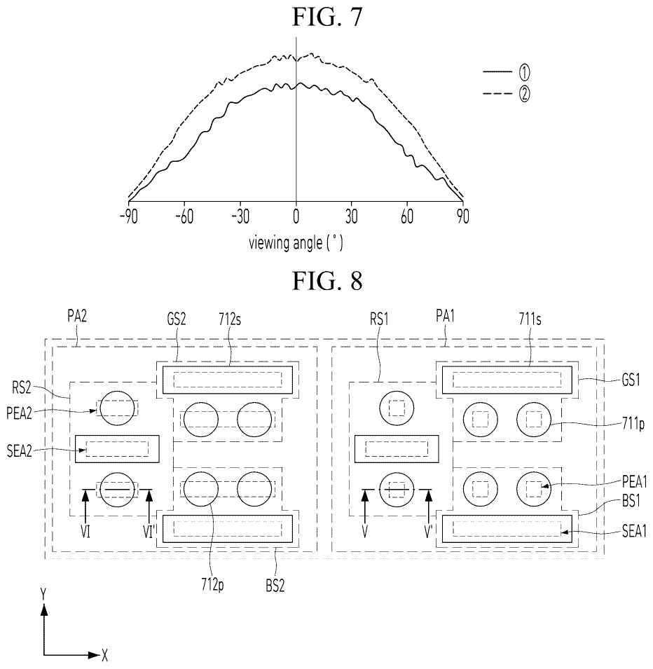

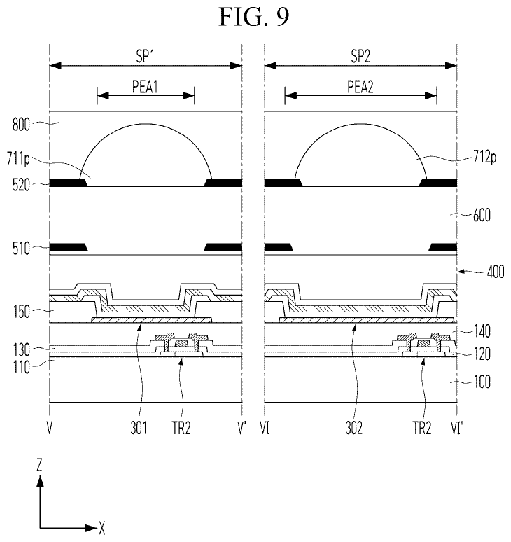

FIG. 2 is an enlarged view of K1 region in FIG. 1. FIG. 3 is an enlarged view of K2 region in FIG. 2. FIG. 4 is a view showing a circuit of a first sub-pixel in the display apparatus according to the embodiment of the present disclosure. FIG. 5 is a view taken along I-I′ and II-II′ of FIG. 2. FIG. 6 is a view taken along III-III′ and IV-IV′ of FIG. 2.

Referring to FIGS. 1 to 6, the display apparatus according to the embodiment of the present disclosure can include a plurality of first pixel areas PA1 within the first display area D1. The plurality of first pixel areas PA1 can be disposed side by side in the first direction X and the second direction Y. For example, the plurality of first pixel areas PA1 can be arranged in a matrix shape or grid arrangement within the first display area D1. Each of the first pixel areas PA1 can display various colors. For example, each of the first pixel areas PA1 can include a plurality of first sub-pixels SP1. Each of the first sub-pixels can display a specific color. For example, each of the first pixel areas PA1 can include a first red sub-pixel RS1 displaying a red color, a first blue sub-pixel BS1 displaying a blue color, and a first green sub-pixel GS1 displaying a green color (also a white sub-pixel can be included).

Various signals can be applied in each first sub-pixel SP1 through signal wirings GL, DL, PL, CL1 and CL2 (e.g., FIG. 4). For example, the signal wirings GL, DL, PL, CL1 and CL2 can include a gate line GL applying a gate signal, a data line DL applying a data signal, and a power voltage supply line PL supplying a power voltage, each of the first sub-pixels SP1 can emit light having luminance corresponding to the data signal according to the gate signal. A driving circuit DC electrically connected to the signal wirings GL, DL, PL, CL1 and CL2 and light-emitting devices 301 and 302 electrically connected to the driving circuit DC can be disposed in each first sub-pixel SP1.

The driving circuit DC can supply a driving current corresponding to the data signal to at least one of the light-emitting devices 301 and 302 according to the gate signal for one frame. For example, the driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the gate line GL, and the first drain electrode can be electrically connected to the data line DL.

The second thin film transistor TR2 can generate the driving current corresponding to the data signal. For example, the second thin film transistor TR2 can function as a driving thin film transistor. The second thin film transistor TR2 can include a second semiconductor pattern 221, a second gate electrode 223, a second drain electrode 225 and a second source electrode 227. For example, the second gate electrode 223 can be electrically connected to the first source electrode, and the second drain electrode 225 can be electrically connected to the power voltage supply line PL.

The second semiconductor pattern 221 can include a semiconductor material. For example, the second semiconductor pattern 221 can include an oxide semiconductor, such as IGZO. The second semiconductor pattern 221 can include a drain region, a channel region and a source region. The channel region can be disposed between the drain region and the source region. A resistance of the drain region and a resistance of the source region can be smaller than a resistance of the channel region. For example, a process of forming the drain region and the source region can include a process of conductorizing a portion of an oxide semiconductor. The channel region can be a region of an oxide semiconductor, which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be disposed on a portion of the second semiconductor pattern 221. For example, the second gate electrode 223 can overlap with the channel region of the second semiconductor pattern 221. The drain region and the source region of the second semiconductor pattern 221 can be disposed outside the second gate electrode 223. The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage of a signal applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. The second drain electrode 225 can be insulated from the second gate electrode 223. For example, the second drain electrode 225 can be disposed on a different layer from the second gate electrode 223. The second drain electrode 225 can be electrically connected to the drain region of the second semiconductor pattern 221.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be insulated from the second gate electrode 223. For example, the second source electrode 227 can be disposed on a different layer from the second gate electrode 223. The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the source region of the second semiconductor pattern 221. The second source electrode 227 can be spaced apart from the second drain electrode 225.

The second source electrode 227 can include a same material as the first source electrode. The second source electrode 227 can be disposed on a same layer as the first source electrode. The second source electrode 227 can be formed by a same process as the first source electrode. For example, the second source electrode 227 can be formed simultaneously with the first source electrode.

The storage capacitor Cst can maintain a voltage of the signal applied to the second gate electrode 223 for one frame. For example, the storage capacitor Cst can be disposed between the second gate electrode 223 and the second source electrode 227. The storage capacitor Cst can have a stacked structure of capacitor electrodes. For example, the storage capacitor Cst can have a structure in which a first capacitor electrode electrically connected to the second gate electrode 233, and a second capacitor electrode electrically connected to the second source electrode 227 are stacked. The storage capacitor Cst can be formed using a process of forming the first thin film transistor TR1 and the second thin film transistor TR2. For example, the first capacitor electrode can be disposed on a same layer as the second gate electrode 223, and the second capacitor electrode can be disposed on a same layer as the second source electrode 227. Thus, in the display apparatus according to the embodiment of the present disclosure, the process efficiency can be improved.

With reference to FIG. 5 and FIG. 6, the driving circuit DC of each first sub-pixel SP1 can be supported by a device substrate 100. For example, the first thin film transistor TR1, the second thin film transistor TR2 and the storage capacitor Cst of each first sub-pixel SP1 can be disposed on an upper surface of the device substrate 100. The device substrate 100 can include an insulating material. For example, the device substrate 100 can include glass or plastic. At least one insulating layers 110, 120, 130, 140 and 150 for preventing or reducing unnecessary electrical connection can be disposed on the upper surface of the device substrate 100. For example, a lower buffer layer 110, a gate insulating layer 120, an interlayer insulating layer 130, a planarization layer 140 and a bank insulating layer 150 can be disposed on the upper surface of the device substrate 100. Also, the driving current from the second thin film transistor (TR2) can be selectively steered to either light-emitting device 301 or light-emitting devices 302, or all of the light-emitting devices (301 and 302), as they can be operatively connected to the same pixel circuit.

The lower buffer layer 110 can include an insulating material. For example, the lower buffer layer 110 can include an inorganic insulating material, such as silicon oxide (SiOx) and silicon nitride (SiNx). The lower buffer layer 110 can have a multi-layer structure. For example, the lower buffer layer 110 can have a structure in which an inorganic insulating layer made of silicon oxide (SiOx) and an inorganic insulating layer made of silicon nitride (SiNx) are stacked. The lower buffer layer 110 can prevent or reduce pollution due to the device substrate 100 in a process of forming the driving circuit DC of each first sub-pixel SP1. For example, the lower buffer layer 110 can be disposed between the driving circuit DC of each first sub-pixel SP1 and the device substrate 100. The upper surface of the device substrate 100 can be covered by the lower buffer layer 110. For example, the driving circuit DC of each first sub-pixel SP1 can be disposed on the lower buffer layer 110.

The gate insulating layer 120 can include an insulating material. For example, the gate insulating layer 120 can include an inorganic insulating material, such as silicon oxide (SiOx) and silicon nitride (SiNx). The gate insulating layer 120 can be disposed on the lower buffer layer 110. The second gate electrode 223 of each first sub-pixel SP1 can be insulated from the second semiconductor pattern 221 of the corresponding first sub-pixel SP1 by the gate insulating layer 120. For example, the gate insulating layer 120 can cover the first semiconductor pattern and the second semiconductor pattern 221 of each first sub-pixel SP1. The first gate electrode and the second gate electrode 223 of each first sub-pixel SP1 can be disposed on the gate insulating layer 120.

The interlayer insulating layer 130 can include an insulating material. For example, the interlayer insulating layer 130 can include an inorganic insulating material, such as silicon oxide (SiOx) and silicon nitride (SiNx). The interlayer insulating layer 130 can be disposed on the gate insulating layer 120. The second drain electrode 225 and the second source electrode 227 of each first sub-pixel SP1 can be insulated from the second gate electrode 223 of the corresponding first sub-pixel SP1 by the interlayer insulating layer 130. For example, the interlayer insulating layer 130 can cover the first gate electrode and the second gate electrode 223 of each first sub-pixel SP1. The first drain electrode, the first source electrode, the second drain electrode 225 and the second source electrode 227 of each first sub-pixel SP1 can be disposed on the interlayer insulating layer 130.

The planarization layer 140 can include an insulating material. The planarization layer 140 can include a different material from the interlayer insulating layer 130. The planarization layer 140 can include a material having a high fluidity or low viscosity. For example, the planarization layer 140 can include an organic insulating material. The planarization layer 140 can be disposed on the interlayer insulating layer 130. A thickness difference or step difference due to the driving circuit DC of each first sub-pixel SP1 can be removed by the planarization layer 140. For example, the first drain electrode, the first source electrode, the second drain electrode 225 and the second source electrode 227 of each first sub-pixel SP1 can be covered by the planarization layer 140. An upper surface of the planarization layer 140 opposite to the device substrate 100 can be flat. For example, the upper surface of the planarization layer 140 can be parallel to the upper surface of the device substrate 100.

The bank insulating layer 150 can include an insulating material. For example, the bank insulating layer 150 can include an organic insulating material. The bank insulating layer 150 can include a different material from the planarization layer 140. The bank insulating layer 150 can be disposed on the upper surface of the planarization layer 140. The bank insulating layer 150 can define a first S-mode emission area SEA1 (e.g., a share viewing mode with a wide viewing angle) and a plurality of first P-mode emission areas PEA1 (e.g., a privacy viewing mode with a narrow viewing angle) in each first sub-pixel SP1. For example, a portion of the upper surface of the planarization layer 140 overlapping with the first S-mode emission area SEA1 defined in each first sub-pixel SP1 and a portion of the upper surface of the planarization layer 140 overlapping with the plurality of first P-mode emission areas PEA1 defined in each first sub-pixel SP1 can be exposed by the bank insulating layer 150.

As shown in FIGS. 2 and 3, each of the first P-mode emission area PEA1 (e.g., privacy viewing mode area) can have a planar shape different from the first S-mode emission area SEA1 (e.g., sharing viewing mode area). For example, a plane of the first S-mode emission area SEA1 can have a bar shape extending in the first direction X, and each of the first P-mode emission areas PEA1 can have a plane of circular shape. The plurality of first P-mode emission areas PEA1 can be disposed side by side, but embodiments are not limited thereto, e.g., a mixed arrangement or different patterns can be provided. The plurality of first P-mode emission areas PEA1 can be disposed parallel to the first S-mode emission area SEA1. For example, the plurality of first P-mode emission areas PEA1 can be disposed side by side on a side of the first S-mode emission area SEA1 in the first direction X.

The first P-mode emission areas PEA1 of each first sub-pixel SP1 can have the number corresponding to a color displayed by the corresponding first sub-pixel SP1. For example, two first P-mode emission areas PEA1 can be defined in each first red sub-pixel RS1, three first P-mode emission areas PEA1 can be defined in each first blue sub-pixel BS1 and each first green sub-pixel GS1 (e.g., 2 red, 3 blue, and 3 green).

As shown in FIG. 5, the light-emitting devices 301 and 302 of each first sub-pixel SP1 can be disposed on the upper surface of the planarization layer 140. The light-emitting devices 301 and 302 of each first sub-pixel SP1 can overlap with the first S-mode emission area SEA1 and the first P-mode emission areas PEA1 of the corresponding first sub-pixel SP1. For example, the light-emitting devices 301 and 302 of each first sub-pixel SP1 can include a first light-emitting device 301 overlapping with the first S-mode emission area SEA1 of the corresponding first sub-pixel SP1 and second light-emitting devices 302 overlapping with the first P-mode emission areas PEA1 of the corresponding first sub-pixel SP1.

The first light-emitting device 301 can emit light displaying a specific color. For example, the first light-emitting device 301 can include a first lower electrode 311, a first light-emitting unit 321 and a first upper electrode 331, which are sequentially stacked on the upper surface of the planarization layer 140 overlapping with the first S-mode emission area SEA1.

The first lower electrode 311 and the first upper electrode 331 can include a conductive material. The first upper electrode 331 can include a different material from the first lower electrode 311. For example, a transmittance of the first upper electrode 331 can be higher than a transmittance of the first lower electrode 311. The first lower electrode 311 can have a higher reflectance than the first upper electrode 331. For example, the first lower electrode 311 can be a reflective electrode including a metal, such as aluminum (Al) and silver (Ag), and the first upper electrode 331 can be a transparent electrode made of a transparent conductive material, such as ITO and IZO.

The first light-emitting unit 321 can generate light having luminance corresponding to a voltage difference between the first lower electrode 311 and the first upper electrode 331. For example, the first light-emitting unit 321 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material. The light generated by the first light-emitting unit 321 can be emitted through the first upper electrode 331.

The first light-emitting unit 321 can further include at least one functional layer. The at least one function layer can be disposed between the first lower electrode 311 and the emission material layer and/or the emission material layer and the first upper electrode 331. Holes and electrons can be smoothly supplied to the emission material layer by the at least one function layer. For example, at least one function layer can be one of a hole injection layer (HIL), a hole transport layer (HTL), an electron transport layer (ETL) and an electron injection layer (EIL).

Each of the second light-emitting devices 302 can overlap with one of the first P-mode emission areas PEA1. Each of the second light-emitting devices 302 can emit light displaying a specific color. For example, each of the second light-emitting devices 302 can include a second lower electrode 312, a second light-emitting unit 322 and a second upper electrode 332, which are sequentially stacked on the upper surface of the planarization layer 140 overlapping with the corresponding first P-mode emission area PEA1.

The light emitted from each second light-emitting device 302 can display a same color as the light emitted from the first light-emitting device 301. For example, the second light-emitting unit 3322 of each second light-emitting device 302 can have a stacked structure same as the first light-emitting unit 321 of the first light-emitting device 301. The second lower electrode 312 of each second light-emitting device 302 can include a same material as the first lower electrode 311 of the first light-emitting device 301. The second lower electrode 312 of each second light-emitting device 302 can be disposed on a same layer as the first lower electrode 311 of the first light-emitting device 301. The second upper electrode 332 of each second light-emitting device 302 can include a same material as the first upper electrode 331 of the first light-emitting device 301. A signal applied to the second upper electrode 332 of each second light-emitting device 302 can be a same as a signal applied to the first upper electrode 331 of the first light-emitting device 301. For example, the second upper electrode 332 of each second light-emitting device 302 can be electrically connected to the first upper electrode 331 of the first light-emitting device 301. The second upper electrode 332 of each second light-emitting device 302 can be in direct contact with the first upper electrode 331 of the first light-emitting device 301. For example, each of the second light-emitting devices 302 can be formed simultaneously with the first light-emitting device 301. Thus, in the display apparatus according to the embodiment of the present disclosure, a process of forming the first light-emitting device 301 and the second light-emitting devices 302 of each first sub-pixel SP1 can be simplified.

Each of the second light-emitting devices 302 can be controlled independently of the first light-emitting device 301. For example, the second lower electrode 312 of each second light-emitting device 302 can be insulated from the first lower electrode 311 of the first light-emitting device 301. A bank insulating layer 150 can be disposed between the second lower electrode 312 of each second light-emitting device 302 and the first lower electrode 311 of the first light-emitting device 301. For example, the first lower electrode 311 of the first light-emitting device 301 and the second lower electrode 312 of each second light-emitting device 302 can include an edge covered by the bank insulating layer 150. The second lower electrode 312 of each second light-emitting device 302 can be spaced apart from the second lower electrode 312 of adjacent second light-emitting device 302.

A color of each first sub-pixel SP1 can be realized by the light emitted from the first light-emitting device 301 of the corresponding first sub-pixel SP1 or the light emitted from the second light-emitting devices 302 of the corresponding first sub-pixel SP1. For example, in the display apparatus according to the embodiment of the present disclosure, an image by the first S-mode emission area SEA1 of each first sub-pixel SP1 or an image by the first P-mode emission areas PEA1 of each first sub-pixel SP1 can be realized at the first display area D1. The driving current generated by the driving circuit DC of each first sub-pixel SP1 can be supplied to the first lower electrode 311 of the corresponding first sub-pixel SP1 or the second lower electrodes 312 of the corresponding first sub-pixel SP1. For example, the signal wirings GL, DL, PL, CL1 and CL2 can include a first control line CL1 applying a first control signal and a second control line CL2 applying a second control signal, a first control thin film transistor TC1 controlled by the first control signal can be disposed between the second thin film transistor TR2 and the first light-emitting device 301 of each first sub-pixel SP1, and a second control thin film transistor TC2 controlled by the second control signal can be disposed between the second thin film transistor TR2 and the second light-emitting devices 302 of each first sub-pixel SP1, as shown in FIG. 4. Thus, in the display apparatus according to the embodiment of the present disclosure, the second source electrode 227 of each first sub-pixel SP1 can be electrically connected to the first lower electrode 311 of the corresponding first sub-pixel SP1 or the second lower electrodes 312 of the corresponding first sub-pixel SP1 by the first control signal and the second control signal. That is, in the display apparatus according to the embodiment of the present disclosure, the first light-emitting device 301 of each first sub-pixel SP1 and the second light-emitting devices 302 of each first sub-pixel SP1 can be selectively operated.

For example, within each sub-pixel, e.g., SP1, a first control transistor TC1 and a second control transistor TC2 can receive separate control signals. These transistors can act as switches to selectively steer a driving current to either a first light-emitting device 301 or a second light-emitting device(s) 302, or both/all. For example, this selection can be achieved by a pair of control transistors, e.g., TC1, TC2 that route the driving current to the desired light-emitting device(s) based on distinct control signals.

An encapsulation structure 400 can be disposed on the first light-emitting device 301 and the second light-emitting devices 302 of each first sub-pixel SP1, as shown in FIG. 5. The encapsulation structure 400 can prevent or reduce the damage of the first light-emitting device 301 and the second light-emitting devices 302 in each first sub-pixel SP1 due to external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can be an inorganic insulating layer made of an inorganic insulating material, and the second encapsulating layer 420 can be an organic insulating layer made of an organic insulating material. A thickness of the second encapsulating layer 420 can be greater than a thickness of the first encapsulating layer 410 and a thickness of the third encapsulating layer 430.

A barrier structure 500 can be disposed on the encapsulation structure 400. The barrier structure 500 can have a multi-layer structure. For example, the barrier structure 500 (e.g., a black matrix) can have a stacked structure of a lower barrier pattern 510 and an upper barrier pattern 520. The lower barrier pattern 510 and the upper barrier pattern 520 can include a material capable of blocking light. For example, the lower barrier pattern 510 and the upper barrier pattern 520 can include a black dye, such as carbon black. The lower barrier pattern 510 and the upper barrier pattern 520 can function as a black matrix. The upper barrier pattern 520 can include a same material as the lower barrier pattern 510. According to another embodiment, rather than having upper and lower barrier patterns, the black matrix can have a plurality of vertical walls or partition walls which can extend partially or all the way through the optical insulating layer 600 and can include a black material or a light absorbing material.

A portion of the lower barrier pattern 510 on each first sub-pixel SP1 can include a first lower S-mode opening 511s corresponding to the first S-mode emission area SEA1 of the corresponding first sub-pixel SP1 and first lower P-mode openings 511p corresponding to the first P-mode emission areas PEA1 of the corresponding first sub-pixel SP1.

The first lower S-mode opening 511s can overlap with the first S-mode emission area SEA1. A plane of the first lower S-mode opening 511s can have a shape corresponding to a plane of the first S-mode emission area SEA1. For example, the first lower S-mode opening 511s can have a planar shape of a bar extending in the first direction X. Each of the first lower P-mode openings 511p can overlap with one of the first P-mode emission areas PEA1. A plane of each first lower P-mode opening 511p can have a shape corresponding to a plane of the corresponding first P-mode emission area PEA1. For example, each of the first lower P-mode openings 511p can have a plane of circular shape.

The lower barrier pattern 510 can overlap with the bank insulating layer 150. The lower barrier pattern 510 can be disposed outside the first S-mode emission area SEA1 and the first P-mode emission areas PEA1 defined in each first sub-pixel SP1. For example, a plane of the first lower S-mode opening 511s on each first sub-pixel SP1 can have a larger size than a plane of the first S-mode emission area SEA1 defined in the corresponding first sub-pixel SP1, each of the first lower P-mode openings 511p on each first sub-pixel SP1 can have a larger plane than one of the first P-mode emission areas PEA1 defined in the corresponding first sub-pixel SP1. The first S-mode emission area SEA1 and the first P-mode emission areas PEA1 of each first sub-pixel SP1 may not overlap with the lower barrier pattern 510.

The upper barrier pattern 520 can be disposed on the lower barrier pattern 510. A portion of the upper barrier pattern 520 on each first sub-pixel SP1 can include a first upper S-mode opening 521s overlapping with the first lower S-mode opening 511s disposed on the corresponding first sub-pixel SP1 and first upper P-mode openings 521p overlapping with the first lower P-mode openings 511p disposed on the corresponding first sub-pixel SP1. For example, the first upper S-mode opening 521s of each first sub-pixel SP1 can overlap with the first S-mode emission area SEA1 of the corresponding first sub-pixel SP1, and each of the first upper P-mode openings 521p on each first sub-pixel SP1 can overlap one of the first P-mode emission areas PEA1 defined in the corresponding first sub-pixel SP1. A plane of the first upper S-mode opening 521s can have a shape corresponding to a plane of the lower S-mode opening 511s. For example, the first upper S-mode opening 521s can have a planar shape of a bar extending in the first direction X. a plane of each first upper P-mode opening 521p can have a shape corresponding to a plane of the corresponding lower P-mode opening 511p. For example, each of the first upper P-mode openings 521p can have a plane of circular shape.

A portion of the upper barrier pattern 520 on each first sub-pixel SP1 can overlap with a portion of the lower barrier pattern 510 disposed on the corresponding first sub-pixel SP1. For example, the upper barrier pattern 520 can be disposed outside the first S-mode emission area SEA1 and the first P-mode emission areas PEA1 defined in each first sub-pixel SP1. The first S-mode emission area SEA1 and the first P-mode emission areas PEA1 of each first sub-pixel SP1 may not overlap with the upper barrier pattern 520. For example, a plane of the first upper S-mode opening 521s of each first sub-pixel SP1 can have a same size as a plane of the first lower S-mode opening 511s disposed on the corresponding first sub-pixel SP1, and each of the first upper P-mode openings 521p on each first sub-pixel SP1 can have a same plane as each first lower P-mode opening 511p disposed on the corresponding first sub-pixel SP1.

The light generated by the first light-emitting device 301 of each first sub-pixel SP1 can be emitted through the first lower S-mode opening 511s and the first upper S-mode opening 521sof the corresponding first sub-pixel SP1. The light generated by each second light-emitting device 302 of each first sub-pixel SP1 can be emitted through one of the first lower P-mode openings 511p and one of the first upper P-mode openings 521p of the corresponding first sub-pixel SP1. Thus, in the display apparatus according to the embodiment of the present disclosure, a travelling direction of the light emitted from the first S-mode emission area SEA1 of each first sub-pixel SP1 and a travelling direction of the light emitted from each first P-mode emission area PEA1 of each first sub-pixel SP1 can be limited by the lower barrier pattern 510 and the upper barrier pattern 520.

The upper barrier pattern 520 can be spaced apart from the lower barrier pattern 510. For example, an optical insulating layer 600 can be disposed between the lower barrier pattern 510 and the upper barrier pattern 520. The optical insulating layer 600 can include an insulating material. The optical insulating layer 600 can include a transparent material. For example, the optical insulating layer 600 can include an inorganic insulating material and/or an organic insulating material. An optical distance of the light emitted from the first S-mode emission area SEA1 of each first sub-pixel SP1 and an optical distance of the light emitted from each first P-mode emission area PEA1 of each first sub-pixel SP1 can be proportional to a thickness of the optical insulating layer 600. Thus, in the display apparatus according to the embodiment of the present disclosure, the light emitted from the first S-mode emission area SEA1 of each first sub-pixel SP1 and the light emitted from each first P-mode emission area PEA1 of each first sub-pixel SP1 can have a sufficient optical distance by the optical insulating layer 600. Therefore, in the display apparatus according to the embodiment of the present disclosure, the quality of the image realized by the first S-mode emission area SEA1 of each first sub-pixel SP1 and the quality of the image realized by the first P-mode emission areas PEA1 of each first sub-pixel SP1 can be improved.

The lower barrier pattern 510 can be covered by the optical insulating layer 600. The lower barrier pattern 510 can be in direct contact with the optical insulating layer 600. For example, the first lower S-mode opening 511s and the first lower P-mode openings 511p of each first sub-pixel SP1 can be filled by the optical insulating layer 600. The upper barrier pattern 520 can be disposed on an upper surface of the optical insulating layer 600 opposite to the device substrate 100. The upper barrier pattern 520 can be in direct contact with the optical insulating layer 600. For example, a portion of the upper surface of the optical insulating layer 600 overlapping with the first S-mode emission area SEA1 of each first sub-pixel SP1 can be exposed by the first upper S-mode opening 521s of the corresponding first sub-pixel SP1, and a portion of the upper surface of the optical insulating layer 600 overlapping with each first P-mode emission area PEA1 of each first sub-pixel SP1 can be exposed by one of the first upper P-mode openings 521p of the corresponding first sub-pixel SP1.

A first S-mode optical lens 711s can be disposed on the upper surface of the optical insulating layer 600 exposed by the first upper S-mode opening 521s of each first sub-pixel SP1. For example, the first S-mode optical lens 711s of each first sub-pixel SP1 can overlap with the first S-mode emission area SEA1 of the corresponding first sub-pixel SP1. The first S-mode optical lens 711s of each first sub-pixel SP1 can function as a convex lens. For example, a surface of the first S-mode optical lens 711s opposite to the optical insulating layer 600 can have a convex shape with respect to the upper surface of the optical insulating layer 600. Thus, in the display apparatus according to the embodiment of the present disclosure, the light emitted from the first S-mode emission area SEA1 of each first sub-pixel SP1 can be concentrated by the first S-mode optical lens 711s of the corresponding first sub-pixel SP1.

The first S-mode optical lens 711s can include an insulating material. For example, the first S-mode optical lens 711s can include a curable resin. The first S-mode optical lens 711s can be in direct contact with the upper surface of the optical insulating layer 600. For example, the first upper S-mode opening 521s can be filled by the first S-mode optical lens 711s. A plane of the first S-mode optical lens 711s can have a larger size than a plane of the first upper S-mode opening 521s. For example, an end of the first S-mode optical lens 711s can overlap with the upper barrier pattern 520. A length of the first S-mode optical lens 711s in the first direction X can be greater than a length of the first S-mode emission area SEA1. Thus, in the display apparatus according to the embodiment of the present disclosure, the light extraction efficiency of the light emitted from the first S-mode emission area SEA1 of each first sub-pixel SP1 can be improved.

A plane of the first S-mode optical lens 711s can have a shape corresponding to a plane of the first upper S-mode opening 521s. For example, the first S-mode optical lens 711s can have a planar shape of a bar extending in the first direction X. Thus, in the display apparatus according to the embodiment of the present disclosure, the light emitted through the first S-mode optical lens 711s of each first sub-pixel SP1 can have a wide viewing angle in the first direction X. For example, in the display apparatus according to the embodiment of the present disclosure, the light passing through the first S-mode optical lens 711s of each first sub-pixel SP1 can travel toward the driver seat DS and the passenger seat PS. Therefore, in the display apparatus according to the embodiment of the present disclosure, the image realized by the first S-mode emission area SEA1 of each first sub-pixel SP1 can be recognized by the driver and the passenger. That is, in the display apparatus according to the embodiment of the present disclosure, the driver and the passenger can share the image realized by the first S-mode emission area SEA1 of each first sub-pixel SP1. For example, in the display apparatus according to the embodiment of the present disclosure, the second image containing information necessary for the operation of the car can be realized by the first S-mode emission area SEA1 of each first sub-pixel SP1.

First P-mode optical lenses 711p can be disposed on the upper surface of the optical insulating layer 600 exposed by the first upper P-mode openings 521p of each first sub-pixel SP1. For example, each of the first P-mode optical lenses 711p on each first sub-pixel SP1 can overlap with one of the first P-mode emission areas PEA1 defined in the corresponding first sub-pixel SP1. Each of the first P-mode optical lenses 711p can function as a convex lens. For example, a surface of each first P-mode optical lens 711p opposite to the optical insulating layer 600 can have a convex shape with respect to the upper surface of the optical insulating layer 600. Thus, in the display apparatus according to the embodiment of the present disclosure, the light emitted from each first P-mode emission area PEA1 of each first sub-pixel SP1 can be concentrated by one of the first P-mode optical lenses 711p on the corresponding first sub-pixel SP1.

Each of the first P-mode optical lenses 711p can include an insulating material. For example, each of the first P-mode optical lenses 711p can include a curable resin. Each of the first P-mode optical lenses 711p can include a same material as the first S-mode optical lens 711s. The first P-mode optical lenses 711p can be disposed on a same layer as the first S-mode optical lens 711s. The first P-mode optical lenses 711p can be formed by a same process as the first S-mode optical lens 711s. For example, the first P-mode optical lenses 711p can be formed simultaneously with the first S-mode optical lens 711s. Each of the first P-mode optical lenses 711p can be in direct contact with the upper surface of the optical insulating layer 600. For example, each of the first upper P-mode openings 521p can be filled by one of the first P-mode optical lenses 711p. A plane of each first P-mode optical lens 711p can have a larger size than a plane of the corresponding first upper P-mode opening 521p. For example, an end of each first P-mode optical lens 711p can overlap with the upper barrier pattern 520. A length of each first P-mode optical lens 711p in the first direction X can be greater than a length of the corresponding first P-mode emission area PEA1 in the first direction X. Thus, in the display apparatus according to the embodiment of the present disclosure, the light extraction efficiency of the light emitted from the first P-mode emission areas PEA1 of each first sub-pixel SP1 can be improved.

A plane of each first P-mode optical lens 711p can have a shape corresponding to a plane of the corresponding first upper P-mode opening 521p. For example, each of the first P-mode optical lenses 711p can have a plane of a circular shape. A cross-section of each first P-mode optical lens 711p in the first direction X can have a semicircular shape. Thus, in the display apparatus according to the embodiment of the present disclosure, the light emitted through each first P-mode optical lens 711p of each first sub-pixel SP1 can have a narrow viewing angle in the first direction X. For example, in the display apparatus according to the embodiment of the present disclosure, the light passing through each first P-mode optical lens 711p of each first sub-pixel SP1 does not travel toward the driver seat DS. That is, in the display apparatus according to the embodiment of the present disclosure, the image realized by the first P-mode emission areas PEA1 of each first sub-pixel SP1 is not recognized by the driver. Therefore, in the display apparatus according to the embodiment of the present disclosure, the gaze dispersion of the driver due to the image realized by the first P-mode emission areas PEA1 of each first sub-pixel SP1 can be prevented or reduced. For example, in the display apparatus according to the embodiment of the present disclosure, the first image containing information unrelated to the operation of the car can be realized by the first P-mode emission areas PEA1 of each first sub-pixel SP1.

In the display apparatus according to the embodiment of the present disclosure, the light emitted through the first S-mode optical lens 711s and the light emitted through each first P-mode optical lens 711p can have a narrow viewing angle in the second direction Y. For example, in the display apparatus according to the embodiment of the present disclosure, the light passing through the first S-mode optical lens 711s and the light passing through each first P-mode optical lens 711p does not travel toward a wind-shield FW of the car. Thus, in the display apparatus according to the embodiment of the present disclosure, the image realized by the first S-mode emission area SEA1 of each first sub-pixel SP1 and the image realized by the first P-mode emission areas PEA1 of each first sub-pixel SP1 is not reflected by the wind-shield FW of the car. Therefore, in the display apparatus according to the embodiment of the present disclosure, the gaze dispersion of the driver can be effectively prevented or at least reduced.

For example, the display apparatus according to the embodiment of the present disclosure can include a sophisticated multi-layer barrier and lens configured for a display to control the viewing angle of light from individual sub-pixels. A barrier structure, e.g., a black matrix with precisely shaped openings, can be built in two or more layers (e.g., 510 and 520) separated by a transparent insulating layer (e.g., 600). This stacked structure can act as an aperture, physically restricting the path of light emitted from different parts of a sub-pixel. This initial control over the light's direction can improve image quality and prevent light from scattering undesirably.

Also, on top of this barrier structure, a series of microlenses (e.g., 711s and 711p) can be provided, each of which can be aligned with a specific opening in the barrier. According to an embodiment, these lenses are not uniform, e.g., they have different shapes to manipulate the light in distinct ways. For example, a rounded bar-shaped lens (e.g., 711s) can be used to create a wide viewing angle to allow an image to be shared (e.g., between both a driver and a passenger). In contrast, circular lenses (e.g., 711p) can be provided to provide a narrow viewing angle, ensuring that a different image is visible only to the passenger and not the driver. This dual lens configuration can effectively allow a single display to show two different pieces of content simultaneously to different viewers to enhance both utility and safety (e.g., preventing driver distraction).

A lens passivation layer 800 can be disposed on the first S-mode optical lens 711s and the first P-mode optical lenses 711p of each first sub-pixel SP1. The lens passivation layer 800 can include an insulating material. The lens passivation layer 800 can include a transparent material. For example, the lens passivation layer 800 can include an inorganic insulating material and/or an organic insulating material. The damage of the first S-mode optical lens 711s and the first P-mode optical lenses 711p due to the external impact can be prevented or reduced by the lens passivation layer 800. For example, the convex surface of the first S-mode optical lens 711s and the convex surface of each first P-mode optical lens 711p opposite to the device substrate 100 can be covered by the lens passivation layer 800. A thickness difference due to the first S-mode optical lens 711s and the first P-mode optical lenses 711p of each first sub-pixel SP1 can be removed by the lens passivation layer 800. For example, an upper surface of the lens passivation layer 800 opposite to the device substrate 100 can be flat.

The first S-mode optical lens 711s and the first P-mode optical lenses 711p of each first sub-pixel SP1 can be in direct contact with the lens passivation layer 800. The lens passivation layer 800 can have a refractive index larger than the first S-mode optical lens 711s and each first P-mode optical lens 711p. Thus, in the display apparatus according to the embodiment of the present disclosure, the reflection of the light emitted from the first S-mode emission area SEA1 of each first sub-pixel SP1 between the first S-mode optical lens 711s of the corresponding first sub-pixel SP1 and the lens passivation layer 800 can be prevented or reduced. And, in the display apparatus according to the embodiment of the present disclosure, the reflection of the light emitted from the first P-mode emission areas PEA1 of each first sub-pixel SP1 between the first P-mode optical lenses 711p of the corresponding first sub-pixel SP1 and the lens passivation layer 800 can be prevented or reduced. Therefore, in the display apparatus according to the embodiment of the present disclosure, the decrease in the light extraction efficiency due to a difference in the refractive index can be prevented or reduced.

For example, a lens passivation layer (e.g., 800) can be disposed over the optical lenses (e.g., 711s and 711p) to help maximize light output and improve image quality. For example, the passivation layer can have a higher refractive index than the lenses it covers. This specific optical property can prevent unwanted internal reflection at the boundary where the lenses and the passivation layer meet. As a result, this configuration can minimize light loss and significantly improves the overall light extraction efficiency of the display.

As shown in FIGS. 2 and 3, the display apparatus according to the embodiment of the present disclosure can include a plurality of second pixel areas PA2 within the second display area D2. The plurality of the second pixel areas PA2 can be arranged in a same shape as the plurality of first pixel areas PA1. For example, the plurality of second pixel areas PA2 can be disposed side by side in the first direction X and the second direction Y. The plurality of the second pixel areas PA2 can be arranged in a matrix shape within the second display area D2.

Each of the second pixel areas PA2 can display various colors. For example, each of the second pixel areas PA2 can include a plurality of second sub-pixels SP2. Each of the second sub-pixels SP2 can display a specific color. For example, each of the second pixel areas PA2 can include a second red sub-pixel RS2 displaying a red color, a second blue sub-pixel BS2 displaying a blue color, and a second green sub-pixel GS2 displaying a green color. Each of the second pixel areas PA2 can have a same configuration as each of the first pixel areas PA1. For example, the second red sub-pixel RS2, the second blue sub-pixel BS2 and the second green sub-pixel GS2 of each second pixel area PA2 can be arranged identically to the first red sub-pixel RS1, the first blue sub-pixel BS1 and the first green sub-pixel GS1 of each first pixel area PA1.

Various signals can be applied in each second sub-pixel SP2 through the signal wirings GL, DL, PL, CL1 and CL2. Each of the second sub-pixels SP2 can have a same configuration as each first sub-pixel SP1. For example, a driving circuit DC electrically connected to the signal wirings GL, DL, PL, CL1 and CL2 and light-emitting devices 301 and 302 electrically connected to the driving circuit DC can be disposed in each second sub-pixel SP2. Each of the second sub-pixel SP2 can emit light having luminance corresponding to the data signal according to the gate signal.

As shown in FIGS. 5 and 6, the lower buffer layer 110, the gate insulating layer 120, the interlayer insulating layer 130, the planarization layer 140, the bank insulating layer 150, the encapsulation structure 400, the barrier structure 500, the optical insulating layer 600 and the lens passivation layer 800 can be sequentially stacked on the second display area D2 of the device substrate 100. The driving circuit DC of each second sub-pixel SP2 can be disposed between the lower buffer layer 110 and the planarization layer 140 of the corresponding second sub-pixel SP2. The bank insulating layer 150 can define a second S-mode emission area SEA2 and a second P-mode emission area PEA2 in each second sub-pixel SP2. The light-emitting devices 301 and 302 of each second sub-pixel SP2 can overlap with the second S-mode emission area SEA2 and the second P-mode emission area PEA2 defined in the corresponding second sub-pixel SP2. For example, the light-emitting devices 301 and 302 of each second sub-pixel SP2 can include the first light-emitting device 301 overlapping with the second S-mode emission area SEA2 of the corresponding second sub-pixel SP2 and the second light-emitting device 302 overlapping with the second P-mode emission area PEA2 of the corresponding second sub-pixel SP2. The first light-emitting device 301 and the second light-emitting device 302 of each second sub-pixel SP2 can be disposed between the planarization layer 140 and the encapsulation structure 400 of the corresponding second sub-pixel SP2.

As shown in FIGS. 2 and 3, the second S-mode emission area SEA2 of each second sub-pixel SP2 can have a planar shape same as the first S-mode emission area SEA1 of each first sub-pixel SP1. For example, the second S-mode emission area SEA2 of each second sub-pixel SP2 can have a planar shape of a bar extending in the first direction X. A plane of the second S-mode emission area SEA2 can have a same size as a plane of the first S-mode emission area SEA1. For example, a length of the second S-mode emission area SEA2 in the first direction X can be a same as or substantially equal to a length of the first S-mode emission area SEA1 in the first direction X.

The second P-mode emission area PEA2 of each second sub-pixel SP2 can have a planar shape different from the first P-mode emission areas PEA1 of each first sub-pixel SP1. For example, the second P-mode emission area PEA2 of each second sub-pixel SP2 can have a planar shape of a bar extending in the first direction X. A plane of the second P-mode emission area PEA2 can be parallel to a plane of the second S-mode emission area SEA2. A plane of the second P-mode emission area PEA2 can have a different size from a plane of the second S-mode emission area SEA2. For example, a length of the second P-mode emission area PEA2 in the first direction X can be different from a length of the second S-mode emission area SEA2 in the first direction X.

The second P-mode emission area PEA2 of each second sub-pixel SP2 can have the number same as the second P-mode emission area PEA2 of the second sub-pixel SP2 displaying a different color from the corresponding second sub-pixel SP2. For example, a single second S-mode emission area SEA2 and a single second P-mode emission area PEA1 can be defined in the second red sub-pixel RS2, the second blue sub-pixel BS2 and the second green sub-pixel GS2 of each second pixel area PA2.

A color of each second sub-pixel SP2 can be realized by light emitted from the first light-emitting device 301 of the corresponding second sub-pixel SP2 or light emitted from the second light-emitting device 302 of the corresponding second sub-pixel SP2. For example, in the display apparatus according to the embodiment of the present disclosure, an image by the second S-mode emission area SEA2 of each second sub-pixel SP2 or an image by the second P-mode emission area PEA2 of each second sub-pixel SP2 can be realized at the second display area D2. The driving current generated by the driving circuit DC of each second sub-pixel SP2 can be supplied selectively to the first light-emitting device 301 of the corresponding second sub-pixel SP2 or the second light-emitting device 302 of the corresponding second sub-pixel SP2. For example, in the display apparatus according to the embodiment of the present disclosure, the first light-emitting device 301 of each second sub-pixel SP2 or the second light-emitting device 302 of each second sub-pixel SP2 can be operated selectively by the first control signal and the second control signal. For example, each second sub-pixel (e.g., SP2) can include independent light-emitting devices (e.g., 301 and 302). First and second control signals can determine which of these light-emitting devices receive the driving current, thereby enabling the selective operation to produce light for an image.

The light-emitting device 301 of each second sub-pixel SP2 can be controlled in a same or similar manner as the first light-emitting device 301 of each first sub-pixel SP1. For example, in the display apparatus according to the embodiment of the present disclosure, the operation of the first light-emitting device 301 on each first sub-pixel SP1 and the operation of the first light-emitting device 301 on each second sub-pixel SP2 can be controlled by the first control signal. The second light-emitting device 302 of each second sub-pixel SP2 can be controlled in a same or similar manner as the second light-emitting devices 302 of each first sub-pixel SP1. For example, in the display apparatus according to the embodiment of the present disclosure, the operation of the second light-emitting devices 302 on each first sub-pixel SP1 and the operation of the second light-emitting device 302 on each second sub-pixel SP2 can be controlled by the second control signal. Thus, in the display apparatus according to the embodiment of the present disclosure, the first light-emitting device 301 of each first sub-pixel SP1 and the first light-emitting device 301 of each second sub-pixel SP2 can be controlled simultaneously by the first control signal, and the second light-emitting devices 302 of each first sub-pixel SP1 and the second light-emitting device 302 of each second sub-pixel SP2 can be controlled simultaneously by the second control signal. Therefore, in the display apparatus according to the embodiment of the present disclosure, the first light-emitting device 301 of each second sub-pixel SP2 can emit light simultaneously with the first light-emitting device 301 of each first sub-pixel SP1, and the second light-emitting device 302 of each second sub-pixel SP2 can emit light simultaneously with the second light-emitting devices 302 of each first sub-pixel SP1.

As shown in FIG. 6, a portion of the lower barrier pattern 510 on each second sub-pixel SP2 can include a second lower S-mode opening 512s corresponding to the second S-mode emission area SEA2 of the corresponding second sub-pixel SP2 and a second lower P-mode opening 512p corresponding to the second P-mode emission area PEA2 of the corresponding second sub-pixel SP2. For example, according to an embodiment, two or more second P-mode optical lenses 712p can overlap with a same second light-emitting device 302.

The second lower S-mode opening 512s can overlap with the second S-mode emission area SEA2. A plane of the second lower S-mode opening 512s can have a shape corresponding to a plane of the second S-mode emission area SEA2. For example, the second lower S-mode opening 512s can have a planar shape of a bar extending in the first direction X. The second lower S-mode opening 512s of each second sub-pixel SP2 can be parallel to the first lower S-mode opening 511s of each first sub-pixel SP1. For example, a plane of the second S-mode opening 512s on each second sub-pixel SP2 can have a same size as a plane of the first S-mode opening 511s on each first sub-pixel SP1.

The lower barrier pattern 510 can be disposed outside the second S-mode emission area SEA2 defined in each second sub-pixel SP2. For example, a plane of the second lower S-mode opening 512s can have a larger size than a plane of the second S-mode emission area SEA2. The second S-mode emission area SEA2 of each second sub-pixel SP2 does not overlap with the lower barrier pattern 510.

The second lower P-mode opening 512p can overlap with the second P-mode emission area PEA2. A plane of the second lower P-mode opening 512p can have a shape corresponding to the second P-mode emission area PEA2. For example, the second lower P-mode opening 512p can have a planar shape of a bar extending in the first direction X. The second lower P-mode opening 512p can be parallel to the second lower S-mode opening 512s. A plane of the second lower P-mode opening 512p can have a different size than a plane of the second lower S-mode opening 512s. For example, a length of the second P-mode opening 512p in the first direction X can be different from a length of the second lower S-mode opening 512s in the first direction X. A plane of the second lower P-mode opening 512s on each second sub-pixel SP2 can have a different shape from a plane of each first lower P-mode opening 511p on each first sub-pixel SP1.

A plane of the second lower P-mode opening 512p can have a smaller size than a plane of the second P-mode emission area PEA2. For example, a length of the second lower P-mode opening 512p in the first direction X can be smaller than a length of the second P-mode emission area PEA2 in the first direction. An edge of the second P-mode emission area PEA2 defined in each second sub-pixel SP2 can overlap with the lower barrier pattern 510.

A portion of the upper barrier pattern 520 on each second sub-pixel SP2 can include a second upper S-mode opening 522s overlapping with the second lower S-mode opening 512s of the corresponding second sub-pixel SP2. A plane of the second upper S-mode opening 522s can have a shape corresponding to a plane of the second lower S-mode opening 512s. For example, the second upper S-mode opening 522s can have a planar shape of a bar extending in the first direction X. A plane of the second upper S-mode opening 522s can have a same size as a plane of the second lower S-mode opening 512s. For example, the second S-mode emission area SEA2 of each second sub-pixel SP2 does not overlap with the upper barrier pattern 520. The second upper S-mode opening 522s of each second sub-pixel SP2 can have a plane having a same size as the first upper S-mode opening 512s of each first sub-pixel SP1.

A portion of the upper barrier pattern 520 on each second sub-pixel SP2 can include a plurality of second upper P-mode openings 522p overlapping with the second lower P-mode opening 512p of the corresponding second sub-pixel SP2. A plane of each second upper P-mode opening 522p can have a different shape from a plane of the second lower P-mode opening 512p. For example, each of the second upper P-mode openings 522p can have a plane of circular shape. A plane of each second upper P-mode opening 522p on each second sub-pixel SP2 can have a same shape as a plane of each first upper P-mode opening 521p on each first sub-pixel SP1. The second upper P-mode openings 522p of each second sub-pixel SP2 can be arranged in a same manner as the first upper P-mode openings 512p of each first sub-pixel SP1. For example, the second upper P-mode openings 522p of each second sub-pixel SP2 can be disposed side by side in the first direction X. The upper barrier pattern 520 can include a region overlapping with the second P-mode emission area PEA2 of each second sub-pixel SP2 between the second upper P-mode openings 522p of the corresponding second sub-pixel SP2.

As shown in FIGS. 2, 3 and 6, a second S-mode optical lens 712s and a plurality of second P-mode optical lenses 712p can be disposed between the optical insulating layer 600 and the lens passivation layer 800 of each second sub-pixel SP2. The second S-mode optical lens 712s can the second P-mode optical lenses 712p can include an insulating material. For example, the second S-mode optical lens 712s and the second P-mode optical lenses 712p can include a curable resin. Each of the second P-mode optical lenses 712p can include a same material as the second S-mode optical lens 712s. The second P-mode optical lenses 712p can be disposed on a same layer as the second S-mode optical lens 712s. The second P-mode optical lenses 712p can be formed by a same process as the second S-mode optical lens 712s. For example, the second P-mode optical lenses 712p can be formed simultaneously with the second S-mode optical lens 712s. The second S-mode optical lens 712s and the second P-mode optical lenses 712p of each second sub-pixel SP2 can be in direct contact with the optical insulating layer 600 and the lens passivation layer 800.

The second S-mode optical lens 712s of each second sub-pixel SP2 can overlap with the second upper S-mode opening 522s of the corresponding second sub-pixel SP2. For example, the second S-mode optical lens 712s of each second sub-pixel SP2 can overlap with the second S-mode emission area SEA2 of the corresponding second sub-pixel SP2. The second S-mode optical lens 712s of each second sub-pixel SP2 can function as a convex lens. For example, a surface of the second S-mode optical lens 712s toward the lens passivation layer 800 can have a convex shape with respect to the upper surface of the optical insulating layer 600. Thus, in the display apparatus according to the embodiment of the present disclosure, the light emitted from the second S-mode emission area SEA2 of each second sub-pixel SP2 can be concentrated by the second S-mode optical lens 712s of the corresponding second sub-pixel SP2.

A plane of the second S-mode optical lens 712s can have a shape corresponding to a plane of the second upper S-mode opening 522s. For example, the second S-mode optical lens 712s can have a planar shape of a bar extending in the first direction X. Thus, in the display apparatus according to the embodiment of the present disclosure, the light emitted through the second S-mode optical lens 712s of each second sub-pixel SP2 can have a wide viewing angle in the first direction X. That is, in the display apparatus according to the embodiment of the present disclosure, the image realized by the second S-mode emission area SEA2 of each second sub-pixel SP2 can be shared with the driver and the passenger. The second S-mode emission area SEA2 of each second sub-pixel SP2 can emit the light simultaneously with the first S-mode emission area SEA1 of each first sub-pixel SP1. Therefore, in the display apparatus according to the embodiment of the present disclosure, the information necessary for the operation of the car can be realized as a single image at the first display area D1 and the second display area D2 by the first S-mode emission area SEA1 of each first sub-pixel SP1 and the second S-mode emission area SEA2 of each second sub-pixel SP2.

The second S-mode optical lens 712s of each second sub-pixel SP2 can be disposed on a same layer as the first S-mode optical lens 711s of each first sub-pixel SP1. For example, the second S-mode optical lens 712s of each second sub-pixel SP2 can be in direct contact with the upper surface of the optical insulating layer 600. The second upper S-mode opening 522s of each second sub-pixel SP2 can be filled by the second S-mode optical lens 712s of the corresponding second sub-pixel SP2. The second S-mode optical lens 712s of each second sub-pixel SP2 can include a same material as the first S-mode optical lens 711s of each first sub-pixel SP1. For example, the second S-mode optical lens 712s of each second sub-pixel SP2 can be formed simultaneously with the first S-mode optical lens 711s of each first sub-pixel SP1.

The second P-mode optical lenses 712p of each second sub-pixel SP2 can overlap with the second upper P-mode openings 522p of the corresponding second sub-pixel SP2. For example, the second P-mode optical lenses 712p of each second sub-pixel SP2 can overlap with the second P-mode emission area PEA2 of the corresponding second sub-pixel SP2. Each of the second P-mode optical lenses 712p can function as a convex lens. For example, a surface of each second P-mode optical lens 712p toward the lens passivation layer 800 can have a convex shape with respect to the upper surface of the optical insulating layer 600. Thus, in the display apparatus according to the embodiment of the present disclosure, the light emitted from the second P-mode emission area PEA2 of each second sub-pixel SP2 can be concentrated by the second P-mode optical lenses 712p of the corresponding second sub-pixel SP2.

Each of the second P-mode optical lenses 712p can overlap one of the second upper P-mode openings 522p. A plane of each second P-mode optical lens 712p can have a shape corresponding to a plane of the corresponding second upper P-mode opening 522p. For example, each of the second P-mode optical lenses 712p can have a plane of circular shape. A plane of the second P-mode optical lens 712p can have a different shape from a plane of the second P-mode emission area PEA2. For example, a length of the second P-mode emission area PEA2 in the first direction X can be greater than a length of each second P-mode optical lens 712p in the first direction X. Thus, in the display apparatus according to the embodiment of the present disclosure, the light passing through the second lower P-mode opening 512p of each second sub-pixel SP2 can be incident to one of the second P-mode optical lens 712p of the corresponding second sub-pixel SP2 via one of the second upper P-mode openings 522p of the corresponding second sub-pixel SP2. Therefore, in the display apparatus according to the embodiment of the present disclosure, the light passing through the second P-mode optical lenses 712p of each second sub-pixel SP2 can have a wider viewing angle in the first direction X than the light passing through the first upper P-mode optical lenses 711p of each first sub-pixel SP1.

For example, according to an embodiment, in the display's second sub-pixel (e.g., SP2), which can be designed for a driver centric viewing area, a special barrier and lens configuration can be used. For example, a lower barrier 510 can define distinct, bar-shaped openings for light emission. Over this, an upper barrier 520 can maintain the bar shape for one opening but strategically places a series of smaller, circular openings over the second bar-shaped opening (e.g., compare FIG. 5 with FIG. 6). This composite structure can precisely channel the light from the emission areas for the lenses.

Further in this example, a corresponding set of optical lenses can be disposed. For example, a single, bar-shaped S-mode lens 712s can be aligned with the first opening to create a wide viewing angle to allow this part of the image to be shared with a passenger, ensuring a seamless look across the entire display. Also, a plurality of individual, circular P-mode lenses 712p can be aligned with each of the small circular openings in the upper barrier. This arrangement can channel light from a wide, bar-shaped emission area through multiple circular lenses to concentrate and directs the light to create a distinct viewing zone intended exclusively for the driver.

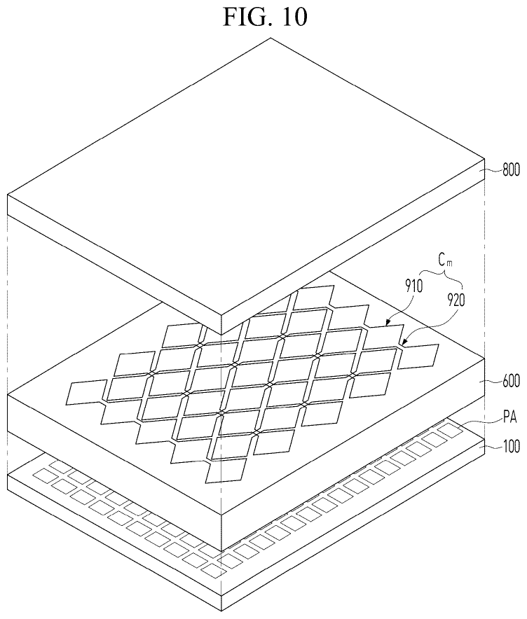

FIG. 7 is a view showing the luminance according to a viewing angle in the first direction X of first light \textcircled{1} emitted from the second P-mode emission area PEA2 and passing through the second P-mode optical lenses 712p on each second sub-pixel SP2 and second light \textcircled{2} emitted from the second S-mode emission area SEA2 and passing through the second S-mode optical lens 712s on each second sub-pixel SP2 in the display apparatus according to the embodiment of the present disclosure.

Referring to FIG. 7, in the display apparatus according to the embodiment of the present disclosure, the first light \textcircled{1} emitted from the second P-mode emission area PEA2 and passing through the second P-mode optical lenses 712p on each second sub-pixel SP2 can have the variation in the luminance according to the viewing angle in the first direction X very similar to the second light \textcircled{2} emitted from the second S-mode emission area SEA2 and passing through the second S-mode optical lens 712s on each second sub-pixel SP2. That is, in the display apparatus according to the embodiment of the present disclosure, the first light \textcircled{1} emitted from the second P-mode emission area PEA2 and passing through the second P-mode optical lenses 712p on each second sub-pixel SP2 can have a wide viewing angle in the first direction X. Thus, in the display apparatus according to the embodiment of the present disclosure, the image realized by the second P-mode emission area PEA2 of each second sub-pixel SP2 can be shared with the driver and the passenger. The second P-mode emission area PEA2 of each second sub-pixel SP2 can emit the light simultaneously with the first P-mode emission areas PEA1 of each first sub-pixel SP1. Therefore, in the display apparatus according to the embodiment of the present disclosure, the image by the second P-mode emission area PEA2 of each second sub-pixel SP2 that is shared with the driver and the passenger can be realized simultaneously with the image by the first P-mode emission areas PEA1 of each first sub-pixel SP1 that is not recognized by the driver. For example, in the display apparatus according to the embodiment of the present disclosure, the first image containing the information unrelated to the operation of the car can be realized in the first display area D1 by the first P-mode emission areas PEA1 of each first sub-pixel SP1, and the second image containing the information necessary for the operation of the car can be realized in the second display area D2 by the second P-mode emission area PEA2 of each second sub-pixel SP2.

As shown in FIGS. 5 and 6, the second P-mode optical lenses 712p of each second sub-pixel SP2 can be disposed on a same layer as the first P-mode optical lenses 711p of each first sub-pixel SP1. For example, each second P-mode optical lens 712p of each second sub-pixel SP2 can be in direct contact with the upper surface of the optical insulating layer 600. Each of the second upper P-mode openings 522p can be filled by the corresponding second P-mode optical lens 712p. The second P-mode optical lenses 712p can include a same material as the first P-mode optical lenses 711p. For example, the second P-mode optical lenses 712p can be formed simultaneously with the first P-mode optical lenses 711p.

As shown in FIGS. 2 and 3, the second S-mode optical lens 712s of each second sub-pixel SP2 can be arranged in a same manner as the first S-mode optical lens 711s of each first sub-pixel SP1, and the second P-mode optical lenses 712p of each second sub-pixel SP2 can be arranged in a same manner as the first P-mode optical lenses 711p of each first sub-pixel SP1. For example, the arrangement of the second S-mode optical lens 712s and the second P-mode optical lenses 712p on the second display area D2 can be a same as the arrangement of the first S-mode optical lens 711s and the first P-mode optical lenses 711p on the first display area D1. Thus, in the display apparatus according to the embodiment of the present disclosure, a profile of external light reflected by the second S-mode optical lens 712s and the second P-mode optical lenses 712p of the second display area D2 can be a same as a profile of the external light reflected by the first S-mode optical lens 711s and the first P-mode optical lenses 711p of the first display area D1. That is, in the display apparatus according to the embodiment of the present disclosure, the unevenness in the reflection of the external light in the first display area D1 and the second display area D2 can be prevented or reduced. Therefore, in the display apparatus according to the embodiment of the present disclosure, the recognition of a boundary between the first display area D1 and the second display area D2 can be prevented or reduced.

Accordingly, the display apparatus according to the embodiment of the present disclosure can provide a single image shared with the driver and the passenger by the first S-mode emission area SEA1 of each first sub-pixel SP1 and the second S-mode emission area SEA2 of each second sub-pixel SP2, and different images to the driver and the passenger by the first P-mode emission area PEA1 of each first sub-pixel SP1 and the second P-mode emission area PEA2 of each second sub-pixel SP2. Thus, in the display apparatus according to the embodiment of the present disclosure, the same image can be provided to the driver and the passenger by the first light-emitting device 301 of each first sub-pixel SP1 and the first light-emitting device 301 of each second sub-pixel SP2, and the different images can be provided to the driver and the passenger by the second light-emitting devices 302 of each first sub-pixel SP1 and the second light-emitting device 302 of each second sub-pixel SP2. That is, in the display apparatus according to the embodiment of the present disclosure, the second light-emitting devices 302 providing the different images to the driver and the passenger can be selectively operated with the first light-emitting devices 301 providing the same image to the driver and the passenger. Therefore, in the display apparatus according to the embodiment of the present disclosure, the decrease in the lifespan due to a different in the deterioration of the light-emitting devices 301 and 302 of the first display area D1 and the light-emitting devices 301 and 302 of the second display area D2 can be prevented or reduced.

And, in the display apparatus according to the embodiment of the present disclosure, the second S-mode optical lens 712s and the second P-mode optical lenses 712p of the second display area D2 can be arranged in a same manner as the first S-mode optical lens 711s and the first P-mode optical lenses 711p of the first display area D1. Thus, in the display apparatus according to the embodiment of the present disclosure, the decrease in the quality of the image due to the unevenness in the reflection of the external light in the first display area D1 and the second display area D2 can be prevented or reduced. That is, in the display apparatus according to the embodiment of the present disclosure, the images having different viewing angles can be realized selectively, without the decrease in the lifespan and the unevenness in the reflection of the external light.

The display apparatus according to the embodiment of the present disclosure is described that the driving circuit DC of each pixel area PA can include the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor pattern. The third gate electrode of each pixel area PA can be electrically connected to one of the gate lines GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in the configuration of the driving circuit DC in each pixel area PA can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

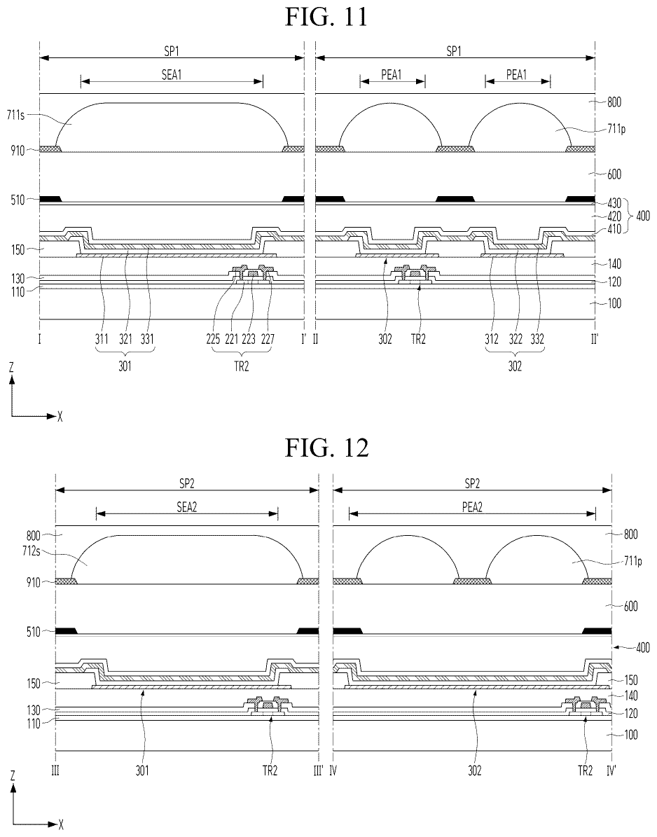

The display apparatus according to the embodiment of the present disclosure is described that the first P-mode emission areas PEA1 of each first sub-pixel SP1 are disposed side by side in the first direction X on a side of the first S-mode emission area SEA1 defined in the corresponding first sub-pixel SP1. However, in the display apparatus according to another embodiment of the present disclosure, the first S-mode emission area SEA1 of each first sub-pixel SP1 can be disposed between the first P-mode emission areas PEA1 of the corresponding first sub-pixel SP1. For example, in the display apparatus according to another embodiment of the present disclosure, each of the first red sub-pixel RS1 and the second red sub-pixel RS2 can include two P-mode emission areas PEA1 and PEA2 and a single S-mode emission area SEA1 and SEA2 disposed between two P-mode emission areas PEA1 and PEA2, as shown in FIGS. 8 and 9.

Each first P-mode optical lens 711p of the first red sub-pixel RS1 can have a larger length in the first direction X than each first P-mode emission area PEA1 of the first red sub-pixel RS1. Each second P-mode optical lens 712p of the second red sub-pixel RS2 can have a smaller length in the first direction X than each second P-mode emission area PEA2 of the second red sub-pixel RS2. Thus, in the display apparatus according to another embodiment of the present disclosure, the degree of freedom in the configuration of each sub-pixel SP1 and SP2 can be improved.

In the display apparatus according to another embodiment of the present disclosure, each of the green sub-pixels GS1 and GS2 or each of the blue sub-pixels BS1 and BS2 can include the S-mode emission area SEA1 and SEA2 disposed between the P-mode emission areas PEA1 and PEA2. And, in the display apparatus according to another embodiment of the present disclosure, a single S-mode emission area SEA1 and SEA2 and a single P-mode emission area PEA1 and PEA2 can be defined in each of the first sub-pixel SP1 and each of the second sub-pixel SP2, and the second P-mode emission area PEA2 of each second sub-pixel SP2 can have a larger plane than the second P-mode optical lens 712p of the corresponding second sub-pixel SP2. Thus, in the display apparatus according to another embodiment of the present disclosure, the decrease in the lifespan and the unevenness in the reflection of the external light can be prevented or reduced, regardless of the configuration of each first sub-pixel SP1 and each second sub-pixel SP2. Therefore, in the display apparatus according to another embodiment of the present disclosure, the degree of freedom in the configuration of each first sub-pixel SP1 and each second sub-pixel SP2 can be improved.

The display apparatus according to the embodiment of the present disclosure is described that the barrier structure 500 has a stacked structure of the lower barrier pattern 510 and the upper barrier pattern 520 including a same material as the lower barrier pattern 510. However, in the display apparatus according to another embodiment of the present disclosure, the upper barrier pattern 520 can include a different material from the lower barrier pattern 510. For example, in the display apparatus according to another embodiment of the present disclosure, a touch sensor Cm can be disposed on the optical insulating layer 600 covering the lower barrier pattern 510, as shown in FIGS. 10 to 12. The touch sensor Cm can sense a touch of the user and/or a tool.

The touch sensor Cm can include touch electrodes 910 and bridge electrodes 920 connecting between the touch electrodes 910. The touch electrodes 910 and the bridge electrodes 920 can include a conductive material. The touch electrodes 910 can include a material capable of blocking light. For example, the touch electrodes 910 can include a metal. At least one of the bridge electrodes 920 can include a different material from the touch electrodes 910. For example, at least one of the bridge electrodes 920 can be disposed on a different layer from the touch electrode 910.

The touch electrodes 910 can overlap with the lower barrier pattern 510 on each first sub-pixel SP1. For example, the first S-mode emission area SEA1 and the first P-mode emission areas PEA1 of each first sub-pixel SP1 does not overlap with the touch electrodes 910. The second S-mode emission area SEA2 of each second sub-pixel SP2 may not overlap with the touch electrodes 910. The touch electrodes 910 disposed between the second P-mode optical lenses 712p of each second sub-pixel SP2 can overlap with the second P-mode emission area PEA2 of the corresponding second sub-pixel SP2. Thus, in the display apparatus according to another embodiment of the present disclosure, the touch electrodes 910 can function as the upper barrier pattern (e.g., providing dual functions of black matrix light blocking and touch sensing). Therefore, in the display apparatus according to another embodiment of the present disclosure, the degree of freedom in the configuration of the barrier structure 500 can be improved.

In the result, the display apparatus according to the embodiments of the present disclosure can comprise the plurality of sub-pixels disposed in the first display area and the second display area, in which the first emission area and the second emission area can be defined in each sub-pixel, in which a plane of the second optical lens disposed on the second emission area can have a different shape from a plane of the first optical lens disposed on the first emission area, in which the second emission area of the first display area can have a planar shape different from the first emission area of the first display area, in which the first emission area of the second displayer area can have a planar shape same as the first emission area of the first display area, and in which the second emission area of the second display area can have a planar shape different from the second emission area of the first display area. Thus, in the display apparatus according to the embodiments of the present disclosure, the second image realized simultaneously with the first image in the second display area can have a different viewing angle from the first image realized in the first display area by the second emission area of each sub-pixel. Thereby, in the display apparatus according to the embodiments of the present disclosure, the images having different viewing angles can be realized simultaneously, without the decrease in the lifespan and the unevenness in the reflection of the external light. And, in the display apparatus according to the embodiments of the present disclosure, the low power operation can be possible, and the power consumption can be reduced.

What is claimed is:

1. A display apparatus comprising:
a bank insulating layer on a device substrate, the bank insulating layer defining a first emission area and a second emission area in a sub-pixel;
an optical insulating layer on the bank insulating layer, the optical insulating layer overlapping with the first emission area and the second emission area;
a first optical lens on the optical insulating layer, the first optical lens overlapping with the first emission area;
a second optical lens on the optical insulating layer, the second optical lens overlapping with the second emission area; and
a lower barrier pattern disposed between the bank insulating layer and the optical insulating layer, the lower barrier pattern including a first lower opening corresponding to the first emission area and a second lower opening corresponding to the second emission area,
wherein the first emission area has a planar shape of a bar extending in a first direction and the second emission area has a planar shape of a bar extending in the first direction, and
wherein a plane of the second optical lens has a different shape from a plane of the first optical lens.

2. The display apparatus according to claim 1, wherein the second optical lens is disposed on a same layer as the first optical lens.

3. The display apparatus according to claim 1, wherein a length of the second emission area in the first direction is different from a length of the first emission area in the first direction.

4. The display apparatus according to claim 1, wherein the second emission area and the first emission area are configured to emit a same color of light.

5. The display apparatus according to claim 1, wherein a length of the first optical lens in the first direction is greater than a length of the first emission area in the first direction, and
wherein a length of the second optical lens in the first direction is smaller than a length of the second emission area.

6. The display apparatus according to claim 5, wherein the first optical lens has a planar shape extending parallel to the first emission area, and
wherein a cross-section of the second optical lens in the first direction has a semicircular shape.

7. The display apparatus according to claim 5, wherein a single first optical lens is disposed within the first emission area, and a plurality of second optical lenses is disposed within the second emission area.

8. The display apparatus according to claim 5, further comprising a plurality of the second optical lenses,
wherein the plurality of the second optical lenses have a same planar shape.

9. The display apparatus according to claim 1, further comprising an upper barrier pattern on the optical insulating layer, the upper barrier pattern overlapping with the lower barrier pattern,
wherein a portion of the upper barrier pattern overlaps with the second emission area.

10. The display apparatus according to claim 9, wherein the upper barrier pattern includes a different material from the lower barrier pattern.

11. A display apparatus, comprising:
a device substrate including a first sub-pixel and a second sub-pixel;
an optical insulating layer on the device substrate, the optical insulating layer overlapping with the first sub-pixel and the second sub-pixel;
a plurality of first optical lenses on the optical insulating layer, the plurality of first optical lenses overlapping with a plurality of first emission areas defined in the first sub-pixel;
a plurality of second optical lenses on the optical insulating layer, the plurality of second optical lenses overlapping with a second emission area defined in the second sub-pixel; and
a lower barrier pattern disposed between the device substrate and the optical insulating layer, the lower barrier pattern including a plurality of first lower openings overlapping with the plurality of first optical lenses and a second lower opening overlapping with the plurality of second optical lenses,
wherein each of the plurality of first emission areas and each of the plurality of first lower openings has a planar shape corresponding to one of the plurality of first optical lenses,
wherein the second emission area and the second lower opening have a planar shape of a bar extending in a first direction, and
wherein a plane of each of the plurality of second optical lenses has a same shape as a plane of each of the plurality of first optical lenses.

12. The display apparatus according to claim 11, wherein the plurality of second optical lenses includes a same material as the plurality of first optical lenses.

13. The display apparatus according to claim 11, wherein the plurality of first optical lenses and the plurality of second optical lenses are disposed side by side in the first direction.

14. The display apparatus according to claim 11, wherein the second sub-pixel and the first sub-pixel are configured to emit a same color of light, and
wherein a number of the plurality of second optical lenses is equal to a number of the plurality of first optical lenses.

15. The display apparatus according to claim 11, further comprising:
a third optical lens on the optical insulating layer, the third optical lens overlapping with a third emission area defined in the first sub-pixel; and
a fourth optical lens on the optical insulating layer, the fourth optical lens overlapping with a fourth emission area defined in the second sub-pixel,
wherein the lower barrier pattern includes a third lower opening corresponding to the third emission area and a fourth lower opening corresponding to the fourth emission area,
wherein a plane of the third emission area and a plane of the fourth emission area extend parallel to a plane of the second emission area, and
wherein the third optical lens and the fourth optical lens have a different planar shape from the plurality of first optical lenses and the plurality of second optical lenses.

16. The display apparatus according to claim 15, wherein the third optical lens and the fourth optical lens are disposed on a same layer as the plurality of first optical lenses and the plurality of the second optical lenses.

17. The display apparatus according to claim 15, wherein a length of the fourth emission area in the first direction is same as a length of the third emission area in the first direction, and
wherein a plane of the fourth optical lens has a same shape as a plane of the third optical lens.
